(19) United States
(12) Patent Application Publication
(10) Pub. No.: US 2022/0293550 A1
(43) Pub. Date: Sep. 15, 2022

(54) SEMICONDUCTOR DEVICE

(71) Applicant: Sumitomo Electric Industries, Ltd., Osaka (JP)

(72) Inventor: Shuichi NISHIMURA, Osaka-shi (JP)

(73) Assignee: Sumitomo Electric Industries, Ltd., Osaka (JP)

(21) Appl. No.: 17/689,056

(22) Filed: Mar. 8, 2022

(30) Foreign Application Priority Data
Mar. 11, 2021 (JP) 2021-039176

(51) Int. Cl. H01L 23/00

(52) U.S. Cl. CPC H01L 24/48; H01L 24/49; H01L 2224/48225; H01L 2224/48195; H01L 2224/4912; H01L 2924/142; H01L 2924/1205

(57) ABSTRACT

A semiconductor device includes a semiconductor chip mounted on an upper surface of a base substrate and having an output pad, a first capacitive component mounted on the upper surface of the base substrate and having one end electrically connected to the base substrate, a frame provided on the base substrate and made of a dielectric surrounding the semiconductor chip and the first capacitive component, an output terminal provided on the frame, a wiring pattern provided on an upper surface of the frame, a first bonding wire electrically connecting the output pad to the output terminal, a second bonding wire electrically connecting another end of the first capacitive component to a first region in the wiring pattern, and a third bonding wire electrically connecting the output pad to a second region different from the first region in the wiring pattern.

### CROSS REFERENCE TO RELATED APPLICATIONS

This application claims priority based on Japanese Patent Application No. 2021-039176 filed on Mar. 11, 2021, and the entire contents of the Japanese patent applications are incorporated herein by reference.

### FIELD

The present disclosure relates to a semiconductor device.

### BACKGROUND

There in known an amplifier in which a semiconductor chip provided with a transistor such as a FET (Field Effect Transistor) is mounted in a package, as a high output amplifier for a microwave. It is known that passive circuits such as an output matching circuit of the amplifier and a video bypass circuit are formed using capacitive components and bonding wires mounted in the package (e.g., Patent Document 1: Japanese Laid-open Patent Publication No. 2014-096497, Patent Document 2: Japanese National Publication of International patent Application No. 2006-501678, Patent Document 3: European Patent Publication No. 3273596, Patent Document 4: Japanese Laid-open Patent Publication No. 2018-101975, Non-Patent Document 1: Hussain Ladhani et.al. “Analysis of the Baseband Termination of High Power RF Transistors” 2019 IEEE/MTT-S International Microwave Symposium, Non-Patent Document 2: Ning Zhu et.al. “Compact High-Efficiency High-Power Wideband GaN Amplifier Supporting 395 MHz Instantaneous Bandwidth” 2019 IEEE/MTT-S International Microwave Symposium).

### SUMMARY

A semiconductor device according to the present disclosure includes a semiconductor chip mounted on an upper surface of a base substrate and having an output pad; a first capacitive component mounted on the upper surface of the base substrate and having one end electrically connected to the base substrate; a frame provided on the base substrate and made of a dielectric surrounding the semiconductor chip and the first capacitive component; an output terminal provided on the frame; a wiring pattern provided on an upper surface of the frame; a first bonding wire electrically connecting the output pad to the output terminal; a second bonding wire electrically connecting another end of the first capacitive component to a first region in the wiring pattern; and a third bonding wire electrically connecting the output pad to a second region different from the first region in the wiring pattern.

A semiconductor device according to the present disclosure includes a semiconductor chip mounted on an upper surface of a base substrate and having an output pad; a first capacitive component mounted on the upper surface of the base substrate and having one end electrically connected to the base substrate; a frame provided on the base substrate and made of a dielectric surrounding the semiconductor chip and the first capacitive component; an output terminal provided on the frame; a wiring pattern provided on an upper surface of the frame and electrically connected to the output terminal on the frame; a first bonding wire electrically connecting the output pad to the output terminal; and a second bonding wire electrically connecting another end of the first capacitive component to a region in the wiring pattern.

### BRIEF DESCRIPTION OF DRAWINGS

FIG. 1 is a circuit diagram illustrating an amplifier having a semiconductor device according to a first embodiment.

FIG. 2 is a circuit diagram illustrating the semiconductor device according to the first embodiment.

FIG. 3 is a plan view illustrating the semiconductor device according to the first embodiment.

FIG. 4 is a cross-sectional view taken along line A-A of FIG. 3.

FIG. 5 is a cross-sectional view taken along line B-B of FIG. 3.

FIG. 6 is a cross-sectional view taken along line C-C of FIG. 3.

FIG. 7 is a plan view illustrating a semiconductor device according to a first comparative example.

FIG. 8 is a plan view illustrating a semiconductor device according to a second comparative example.

FIG. 9 is a circuit diagram illustrating a semiconductor device according to a first variation of the first embodiment.

FIG. 10 is a plan view illustrating a semiconductor device according to a first variation of the first embodiment.

FIG. 11 is a plan view illustrating a semiconductor device according to a second variation of the first embodiment.

FIG. 12 is a plan view illustrating a semiconductor device according to a third variation of the first embodiment.

FIG. 13 is a plan view illustrating a semiconductor device according to a fourth variation of the first embodiment.

FIG. 14 is a circuit diagram illustrating a VBW circuit according to a fifth variation of the first embodiment.

FIG. 15 is a circuit diagram illustrating a VBW circuit according to a sixth variation of the first embodiment.

FIG. 16 is a plan view illustrating a semiconductor device according to the sixth variation of the first embodiment.

FIG. 17 is a circuit diagram illustrating a VBW circuit according to a seventh variation of the first embodiment.

FIG. 18 is a circuit diagram illustrating a VBW circuit according to an eighth variation of the first embodiment.

FIG. 19 is a plan view illustrating a semiconductor device according to the eighth variation of the first embodiment.

### DETAILED DESCRIPTION OF EMBODIMENTS

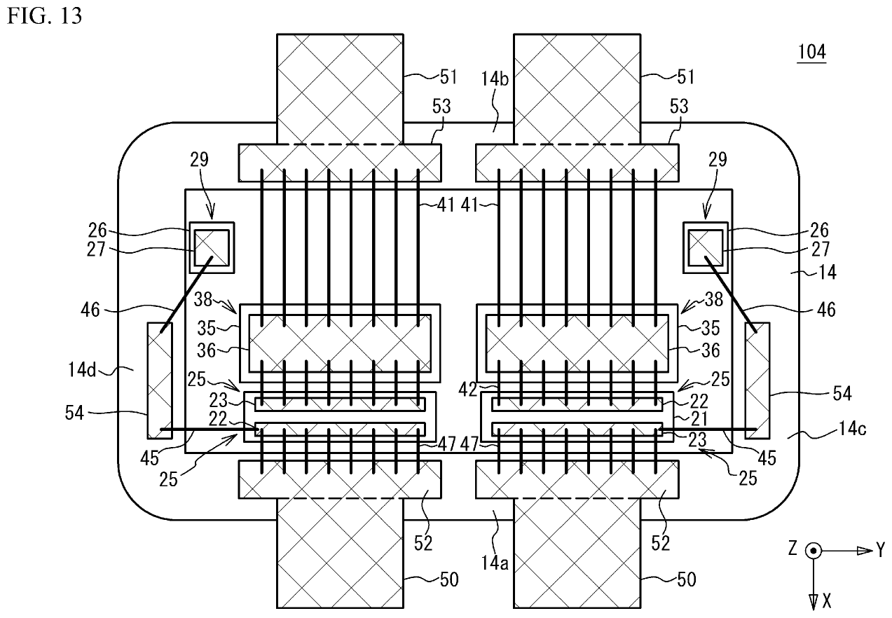

When an inductor and a capacitor are connected in series between an output pad of the semiconductor chip and a ground, the capacitive component is mounted on a base substrate, and the capacitive component and the output of the semiconductor chip are connected by using a bonding wire. However, if an attempt is made to increase an inductance, the bonding wire becomes long and the package becomes large. As illustrated in FIG. 13 of Patent Document 1, for example, it is conceivable to form a part of an inductor by using a wiring component. However, if the wiring component such as a microstrip line is mounted inside the package, the size of the package becomes large, and a manufacturing cost increases.

It is an object of the present disclosure to provide a semiconductor device that can reduce size and cost.

### DESCRIPTION OF EMBODIMENTS OF THE PRESENT DISCLOSURE

First, the contents of the embodiments of this disclosure are listed and explained.

(1) A semiconductor device according to the present disclosure includes a semiconductor chip mounted on an upper surface of a base substrate and having an output pad; a first capacitive component mounted on the upper surface of the base substrate and having one end electrically connected to the base substrate; a frame provided on the base substrate and made of a dielectric surrounding the semiconductor chip and the first capacitive component; an output terminal provided on the frame; a wiring pattern provided on an upper surface of the frame; a first bonding wire electrically connecting the output pad to the output terminal; a second bonding wire electrically connecting another end of the first capacitive component to a first region in the wiring pattern; and a third bonding wire electrically connecting the output pad to a second region different from the first region in the wiring pattern. This makes it possible to provide the semiconductor device that can reduce size and cost.
(2) The semiconductor device may include an input terminal provided on the frame, facing the output terminal across the semiconductor chip, and electrically connected to an input pad of the semiconductor chip. An angle between a direction in which the third bonding wire extends and a direction in which the input terminal, the semiconductor chip and the output terminal are arranged may be 30 degrees or more.
(3) The semiconductor chip may amplify a high frequency signal and outputs the amplified high frequency signal to the output pad. An absolute value of a total impedance of the second bonding wire, the third bonding wire and the wiring pattern at a frequency of the high frequency signal amplified by the semiconductor chip may be greater than an absolute value of an impedance of the first capacitive component at a frequency corresponding to a bandwidth of the high frequency signal amplified by the semiconductor chip.
(4) A semiconductor device according to the present disclosure includes a semiconductor chip mounted on an upper surface of a base substrate and having an output pad; a first capacitive component mounted on the upper surface of the base substrate and having one end electrically connected to the base substrate; a frame provided on the base substrate and made of a dielectric surrounding the semiconductor chip and the first capacitive component; an output terminal provided on the frame; a wiring pattern provided on an upper surface of the frame and electrically connected to the output terminal on the frame; a first bonding wire electrically connecting the output pad to the output terminal; and a second bonding wire electrically connecting another end of the first capacitive component to a region in the wiring pattern.
(5) The semiconductor chip may amplify a high frequency signal and outputs the amplified high frequency signal to the output pad. An absolute value of a total impedance of the second bonding wire and the wiring pattern at a frequency of the high frequency signal amplified by the semiconductor chip may be greater than an absolute value of an impedance of the first capacitive component at a frequency corresponding to a bandwidth of the high frequency signal amplified by the semiconductor chip.
(6) The semiconductor device may include an input terminal provided on the frame and electrically connected to an input pad of the semiconductor chip.
(7) The semiconductor device may include an external terminal electrically connected to the wiring pattern and connected to an external capacitive component.
(8) The first bonding wire may not be connected to another capacitive component mounted on the base substrate, but connect the output pad to the output terminal.
(9) The semiconductor device may include a second capacitive component mounted on the upper surface of the base substrate and having one end electrically connected to the base substrate. The first bonding wire may include a fourth bonding wire electrically connecting the output pad to another end of the second capacitive component, and a fifth bonding wire electrically connecting the another end of the second capacitive component to the output terminal.

### DETAILS OF EMBODIMENTS OF THE PRESENT DISCLOSURE

Specific examples of a semiconductor device in accordance with embodiments of the present disclosure are described below with reference to the drawings. The present disclosure is not limited to these examples, but is indicated by the claims, which are intended to include all modifications within the meaning and scope of the claims.

### First Embodiment

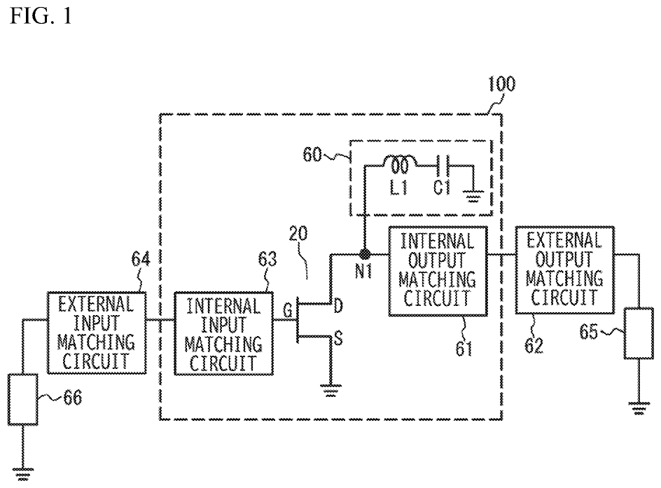

FIG. 1 is a circuit diagram illustrating an amplifier having a semiconductor device according to a first embodiment. As illustrated in FIG. 1, the amplifier includes a semiconductor device 100, an external output matching circuit 62, and an external input matching circuit 64. The semiconductor device 100 includes a transistor 20, an internal output matching circuit 61, an internal input matching circuit 63, and a VBW (Video Bandwidth) circuit 60. The transistor 20 is, for example, a GaN HEMT (Gallium Nitride High Electron Mobility Transistor) or an LDMOS (Laterally Different Metal Oxide Semiconductor). An input load 66 is connected to a gate G of the transistor 20 via the external input matching circuit 64 and the internal input matching circuit 63. The external input matching circuit 64 and the internal input matching circuit 63 match the input load 66 with an input impedance of the transistor 20.

A source S of the transistor 20 is grounded. A drain D of the transistor 20 is connected to an output load 65 via the internal output matching circuit 61 and the external output matching circuit 62. The internal output matching circuit 61 and the external output matching circuit 62 match the output load 65 with an output impedance of the transistor 20. A node N1 between the drain D of the transistor 20 and the internal output matching circuit 61 is grounded via the VBW circuit 60. The VBW circuit 60 includes an inductor L1 and a capacitor C1 connected in series between the node N1 and the ground.

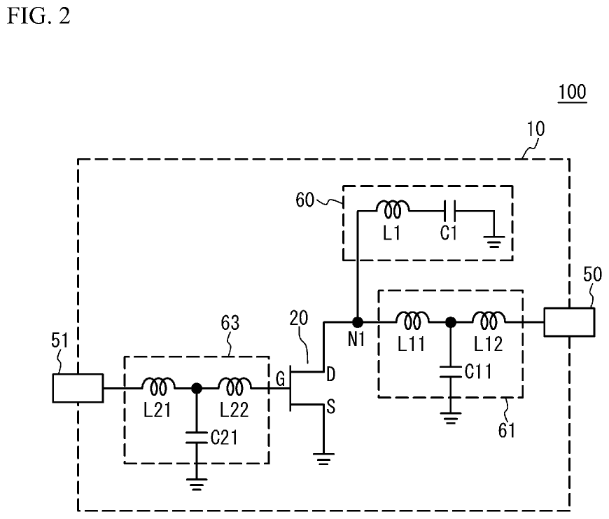

FIG. 2 is a circuit diagram illustrating the semiconductor device according to the first embodiment. As illustrated in FIG. 2, the semiconductor device 100 includes a package 10. The transistor 20, the internal output matching circuit 61, the internal input matching circuit 63, and the VBW circuit 60 are mounted in the package 10. An output lead 50 and an input lead 51 connect the circuits in the package 10 to the outside. The internal output matching circuit 61 is an L-C-L T-type circuit, and includes inductors L11 and L12 and a capacitor C11. The internal input matching circuit 63 is the LCL T-type circuit, and includes inductors L21 and L22 and a capacitor C21.

The VBW circuit 60 is a circuit for improving VBW (i.e., a video bandwidth). The video bandwidth is used as an indicator of a distortion bandwidth. When VBW is small, measurement of the third order intermodulation distortion (IMD3) of a two-tone signal corresponding to the bandwidth of the amplifier (e.g., 400 MHz) results in a difference in signal strength between the IMD3 component on the low frequency side and the IMD3 component on the high frequency side. When asymmetry occurs in the IMD3 in this way, distortion compensation using DPD (Digital Predistortion) cannot provide sufficient distortion characteristics because the amount of distortion improvement is reduced (see, for example, Non-Patent Document 1). A cause of this asymmetry of the IMD3 is known to be a second-order intermodulation distortion IMD2 component generated in the difference frequency component of the two-tone signal. For this reason, by installing the VBW circuit 60, the impedance of the low frequency band at the node N1 is reduced, thereby increasing the video bandwidth and suppressing the IMD2 component. This improves the asymmetry of the IMD3 and allows the DPD to provide sufficient distortion compensation.

The inductor L1 has a function of suppressing a high frequency signal of a fundamental wave amplified by the amplifier (for example, 1 GHz or more, for example, 1.8 GHz or 2.4 GHz) from passing through the capacitor C1 to the ground. Therefore, the inductor L1 has an inductance such that it has a high impedance in the frequency band of the fundamental wave. The capacitor C1 has a low impedance at a frequency (for example, 0 to 400 MHz) corresponding to the bandwidth of the high frequency signal amplified by the amplifier. Therefore, the capacitor C1 has a large capacitance value and becomes large in size.

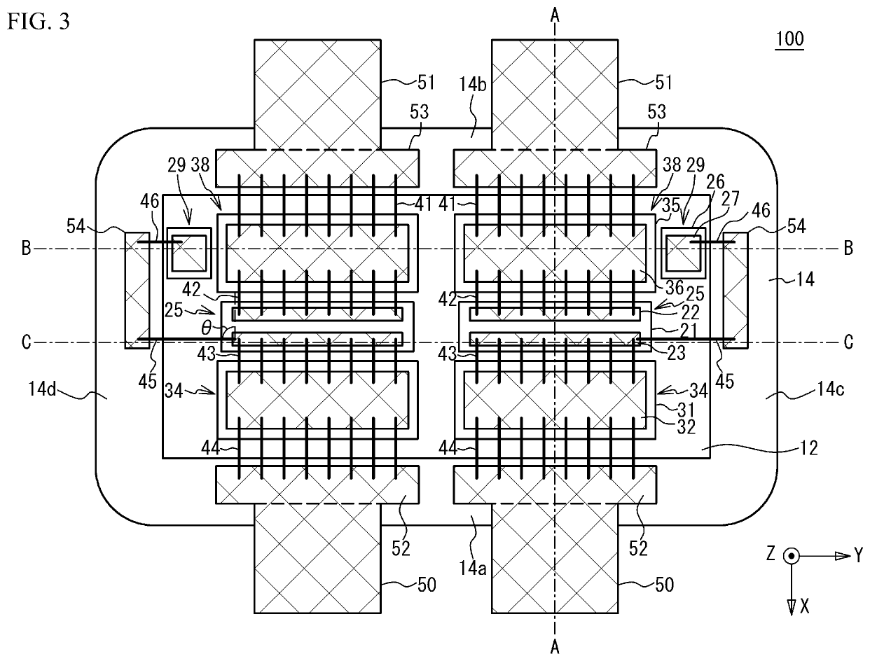

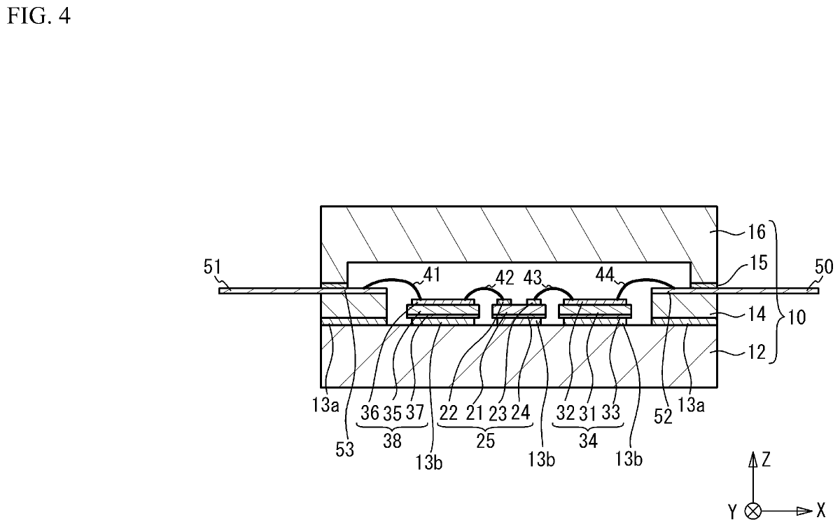

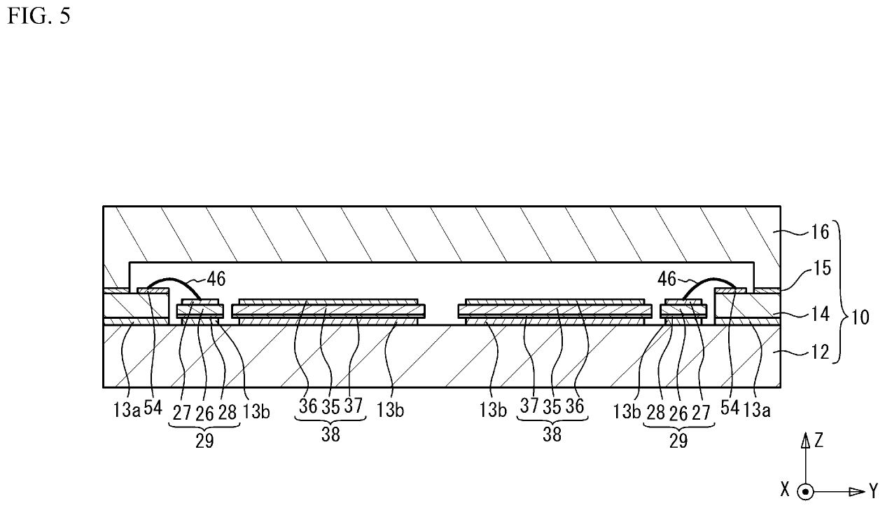

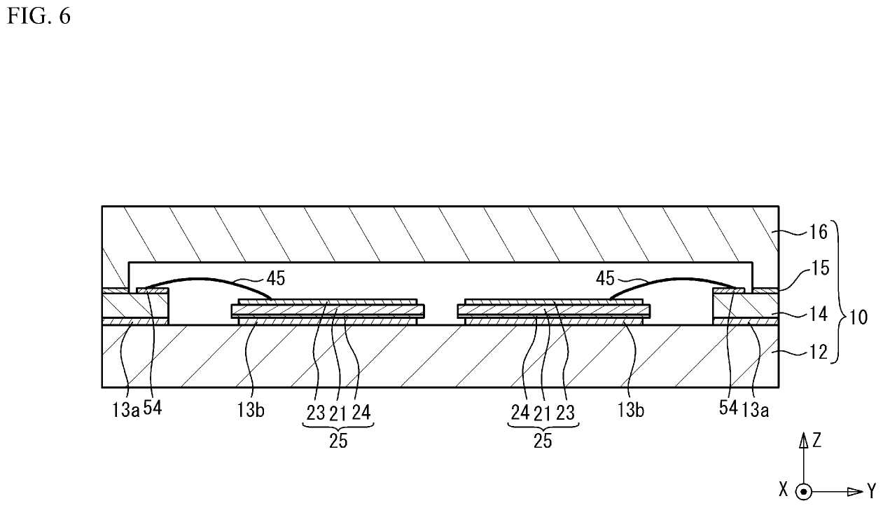

FIG. 3 is a plan view illustrating the semiconductor device according to the first embodiment. FIGS. 4 to 6 are cross-sectional views taken along line A-A, line B-B, line C-C of FIG. 3, respectively. A lid is not illustrated in FIG. 3. A normal direction of the upper surface of the base substrate 12 is a Z direction, a direction from the input lead 51 to the output lead 50 is an X direction, and directions orthogonal to the X direction and the Z direction are a Y direction.

As illustrated in FIGS. 3 to 6, in the semiconductor device 100 of the first embodiment, the package 10 has a base substrate 12, a frame 14, and a lid 16. The base substrate 12 is a conductive substrate such as a laminated substrate of copper and molybdenum. A reference potential such as a ground potential is supplied to the base substrate 12. The frame 14 and the lid 16 are dielectric layers made of a resin such as Flame Retardant Type 4 (FR-4), or ceramic. Semiconductor chips 25 and capacitive components 29, 34 and 38 are mounted on the base substrate 12. Two semiconductor chips 25 are provided. Corresponding to the semiconductor chips 25, two input leads 51, two output leads 50, and two capacitive components 29, 34, and 38 are provided. The two semiconductor chips 25 correspond to, for example, a carrier amplifier and a peak amplifier of a Doherty amplifier circuit. The semiconductor chip 25, the input lead 51, the output lead 50, and the capacitive components 29, 34, and 38 may all be one. The two semiconductor chips 25, the two capacitive components 34, and the two capacitive components 38 are each arranged in the Y direction. The frame 14 is provided on the base substrate 12 so as to surround the semiconductor chip 25 and the capacitive components 29, 34, and 38. The frame 14 is bonded to the upper surface of the base substrate 12 by a bonding layer 13a such as a metal paste or a brazing material. The lid 16 is joined to the upper surface of the frame 14 by an insulating adhesive 15 such as a resin. The frame 14 and the lid 16 seal the semiconductor chip 25 in a space.

A planar shape of the frame 14 is a substantially rectangle. Four sides of the rectangle have opposing sides 14a and 14b, and sides 14c and 14d intersecting the sides 14a and 14b. Wiring patterns 54, output patterns 52, and input patterns 53 are provided on the frame 14. The output leads 50 are formed of the same metal layers as the output patterns 52, and the input leads 51 are formed of the same metal layers as the input patterns 53. The output leads 50 and the input leads 51 may be electrically bonded to the output patterns 52 and the input patterns 53, respectively, with, for example, the metal paste or the brazing material. The output patterns 52 and the input patterns 53 are provided on the opposite sides 14a and 14b, respectively, and the wiring patterns 54 are provided on the sides 14c and 14d. The output leads 50 extend from the output patterns 52 in the +X direction, and the input leads 51 extend from the input patterns 53 in the −X direction. The wiring patterns 54, the output patterns 52, and the input patterns 53 are metal layers such as a gold layer or a copper layer. The input leads 51 and the output leads 50 are metal layers such as the gold layer or the copper layer.

The semiconductor chip 25 includes a semiconductor substrate 21, electrodes 22 and 23 provided on the upper surface of the semiconductor substrate 21, and an electrode 24 formed on the lower surface of the semiconductor substrate 21. The electrodes 22, 23 and 24 are a gate electrode, a drain electrode and a source electrode, respectively, and the electrodes 22 and 23 are an input pad and an output pad, respectively. The electrodes 22, 23 and 24 are metal layers such as the gold layer. The capacitive components 29, 34 and 38 include the dielectric substrates 26, 31 and 35, the electrodes 27, 32 and 36 provided on the upper surfaces of the dielectric substrates 26, 31 and 35, the electrodes 28, 33 and 37 provided on the lower surfaces of the dielectric substrates 26, 31 and 35, respectively Capacitors are formed by the electrodes 27, 32 and 36 and the electrodes 28, 33 and 37 sandwiching the dielectric substrates 26, 31 and 35, respectively. The dielectric substrates 26, 31 and 35 are, for example, alumina, and the electrodes 27, 28, 32, 33, 36 and 37 are metal layers such as the gold layer. The electrodes 24, 28, 33 and 37 are electrically bonded to the base substrate 12 by a bonding layer 13b such as the metal paste or the brazing material.

A bonding wire 41 electrically connects the input pattern 53 and the electrode 36. A bonding wire 42 electrically connects the electrode 36 to the electrode 22. A bonding wire 43 electrically connects the electrodes 23 to the electrode 32. A bonding wire 44 electrically connects the electrode 32 to the output pattern 52. The bonding wires 41 to 44 extend in the X direction in a plan view. The bonding wire 45 electrically connects the electrode 23 to an end portion of the wiring pattern 54 in the +X direction. The bonding wire 46 electrically connects the electrode 27 to an end portion of the wiring pattern 54 in the −X direction. The bonding wires 41 to 46 are, for example, gold wires or aluminum wires.

The bonding wires 41 to 44 correspond to inductors L21, L22, L11 and L12 in FIG. 2, respectively. Capacitive components 34 and 38 correspond to capacitors C21 and C11 in FIG. 2, respectively. The capacitive component 29 corresponds to a capacitor C1 in FIG. 2. The bonding wire 45, the wiring pattern 54, and the bonding wire 46 correspond to an inductor L1 in FIG. 2.

### First Comparative Example

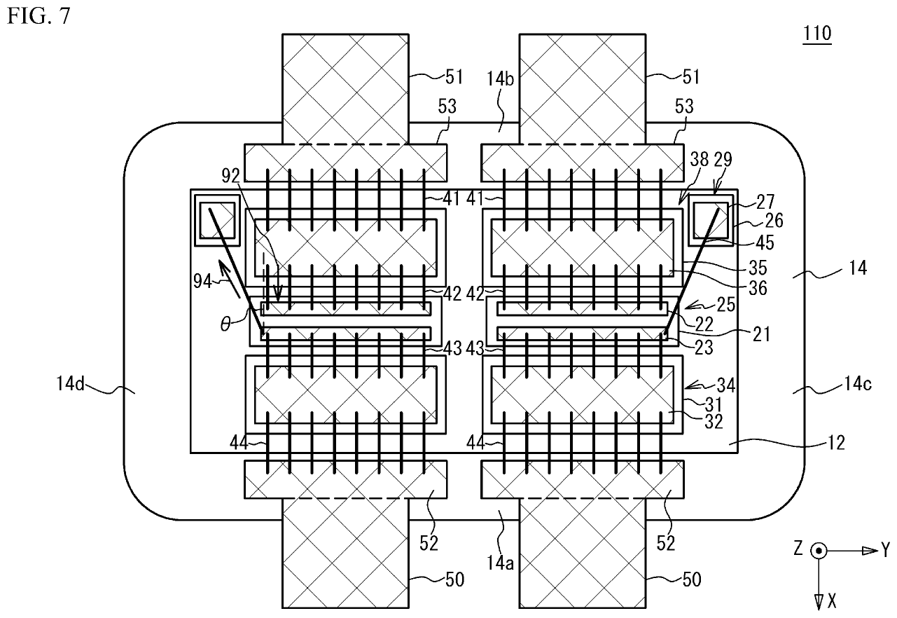

FIG. 7 is a plan view illustrating a semiconductor device according to a first comparative example. As illustrated in FIG. 7, in a semiconductor device 110 of the first comparative example, the wiring pattern 54 is not provided, and the electrode 23 of the semiconductor chip 25 and the electrode 27 of the capacitive component 29 are connected by the bonding wire 45. Other configurations are the same as those in the first embodiment.

The impedance of the inductor L1 of the VBW circuit 60 is almost open in the fundamental wave. Therefore, the inductance of the inductor L1 is, for example, about 2 nH. When the inductor L1 is formed by using the bonding wire 45, the bonding wire 45 is lengthened. An allowable current of the bonding wire 45 is inversely proportional to the length of the bonding wire 45. If the bonding wire 45 is long, it may be fused by the flowing current. As a countermeasure against fusion, it is conceivable to provide a plurality of bonding wires 45 in parallel. When trying to obtain the same inductance (for example, 2 nH), it is necessary to make the bonding wire 45 longer by two bonding wires 45 in parallel than by one bonding wire 45. Therefore, even if the two bonding wires 45 are arranged in parallel, the allowable current becomes less than twice the current, and an effect of improving the fusion is small.

Further, when the bonding wire 45 is extended in the Y direction, the size of the package 10 is increased in the Y direction. Therefore, the bonding wire 45 is extended diagonally to the X direction. In order to reduce the width of the package 10 in the Y direction, an angle θ between the extension direction of the bonding wire 45 and the X direction is 30 degrees or less, for example. The direction of the current in the bonding wire 42 is in the +X direction as illustrated by an arrow 92. The direction of the current in the bonding wire 45 is the −X direction as illustrated by an arrow 94. Therefore, a coupling due to the mutual inductance between the bonding wires 42 and 45 becomes large. This causes a large coupling due to the mutual inductance between bonding wires 42 and 45. This may cause the amplifier to oscillate.

It is also conceivable to provide the capacitive component 29 outside the package 10. However, if the capacitive component 29 is externally attached, the distance between the semiconductor chip 25 and the capacitive component 29 becomes long, and the inductance of the inductor L1 becomes too large. In such a case, the capacitive component 29 is mounted inside the package 10.

### Second Comparative Example

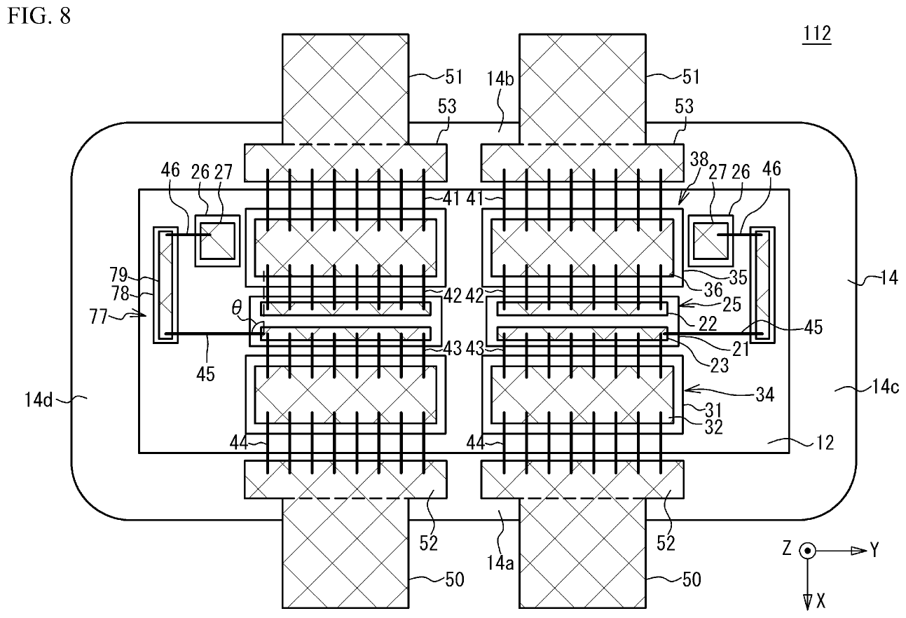

FIG. 8 is a plan view illustrating a semiconductor device according to a second comparative example. As illustrated in FIG. 8, in the semiconductor device 112 of the second comparative example, a wiring component 77 is provided on the base substrate 12. The wiring component 77 includes a dielectric substrate 78 and a wiring pattern 79 provided on the upper surface of the dielectric substrate 78. The bonding wire 45 electrically connects the electrode 23 to the wiring pattern 79. The bonding wire 46 electrically connects the electrode 27 to the wiring pattern 79. The inductor L1 is formed by the bonding wire 45, the wiring pattern 79, and the bonding wire 46. Each of the bonding wires 45 and 46 can be shorter than the bonding wire 45 of the first comparative example. This makes it possible to suppress the fusion of the bonding wire 45.

Also, the angle θ between the extension direction of the bonding wire 45 and the extension direction of the bonding wire 42 can be set to 30 degrees or more. Thereby, the mutual inductance between the bonding wires 42 and 45 can be reduced, and the coupling can be reduced. This can suppress the oscillation of the amplifier.

However, in order to provide the wiring component 77 in the frame 14, it is necessary to mount the wiring component 77 on the base substrate 12. Therefore, a space is required between the frame 14 and the wiring component 77 and between the other component and the wiring component 77, and hence the package becomes large. Further, the cost increase due to the component cost of the wiring component 77 occurs and the cost increase due to the work cost for mounting the wiring component 77 on the base substrate 12 occurs.

According to the first embodiment, as illustrated in FIGS. 3 to 6, the output lead 50 and the output pattern 52 (output terminal) are provided on the frame 14. The wiring pattern 54 is provided on the upper surface of the frame 14. The electrode 28 (one end) of the capacitive component 29 is electrically connected to the base substrate 12. The bonding wires 43 and 44 (first bonding wire) electrically connect the electrode 23 (output pad) of the semiconductor chip 25 to the output pattern 52. The bonding wire 46 (second bonding wire) electrically connects the electrode 27 (another end) of the capacitive component 29 (first capacitive component) to a first region of the wiring pattern 54. The bonding wire 45 (third bonding wire) electrically connects the electrode 23 of the semiconductor chip 25 to a second region different from the first region of the wiring pattern 54.

In this way, the bonding wire 45, the wiring pattern 54 and the bonding wire 46 function as the inductor L1. Thereby, even when forming the inductor L1 having a large inductance, it is not necessary to use the long bonding wire 45 as in the first comparative example. Therefore, it is possible to suppress the fusion of the bonding wire 45. Further, by providing the wiring pattern 54 on the frame 14, it is not necessary to provide the wiring component 77 as in the second comparative example. In the first embodiment, the wiring pattern 54 is formed on the frame 14 by using the same film forming process as the output pattern 52, for example. Therefore, the first embodiment can reduce the component cost of the wiring component 77 and the cost of the process of mounting the wiring component 77 on the base substrate 12 as in the second comparative example.

In the second comparative example, the space for the mounting process is required between the wiring component 77, and the other components and the frame 14. In the first embodiment, since the wiring pattern 54 is provided on the frame 14, the space between the wiring pattern 54 and the frame 14 is not required, thereby reducing the size.

The input lead 51 and the input pattern 53 (input terminal) electrically connected to the electrode 22 (input pad) of the semiconductor chip 25 are provided on the frame 14, and face the output lead 50 and the output pattern 52 across the semiconductor chip 25. Thereby, the high frequency signal input from the input lead 51 and the input pattern 53 is input to the electrode 22 of the semiconductor chip 25.

At least a part of the wiring pattern 54 is located in the Y direction orthogonal to the X direction in which the input lead 51, the semiconductor chip 25 and the output lead 50 are arranged with respect to the semiconductor chip 25. Thereby, the angle between the bonding wire 45 and the bonding wires 42 and 43 can be increased. Therefore, the coupling between the bonding wire 45, and the bonding wires 42 and 43 as in the first comparative example can be suppressed. This can suppress the oscillation of the amplifier. The angle θ between the extension direction of the bonding wire 45 and the X direction is preferably 30 degrees or more, more preferably 45 degrees or more, and still more preferably 75 degrees or more. As a result, the coupling between the bonding wire 45, and the bonding wires 42 and 43 can be suppressed, and the oscillation of the amplifier can be suppressed.

The semiconductor chip 25 includes the transistor 20 that amplifies the high frequency signal input from the electrode 22 and outputs the high frequency signal to the electrode 23. An absolute value “2πfL1” of a total impedance ZL of the bonding wires 45, 46 and the wiring pattern 54 forming the inductor L1 at a frequency f of the fundamental wave (the high frequency signal mainly amplified by the transistor 20 of the semiconductor chip 25) is greater than an absolute value “1/(2πΔfC1)” of an impedance ZC of the capacitor C1 at the frequency Δf corresponding to the bandwidth of the capacitive component 29. Thereby, the inductor L1 suppresses the passage of the high frequency signal having the frequency f of the fundamental wave, and the capacitor C1 passes the high frequency signal having the frequency Δf corresponding to the bandwidth. Therefore, the inductor L1 and the capacitor C1 function as the VBW circuit 60. The absolute value of impedance ZL is preferably 10 dB or more larger than the absolute value of impedance ZC, and more preferably 20 dB or more.

The electrode 33 (one end) of the capacitive component 34 (second capacitive component) is electrically connected to the base substrate 12. The bonding wire 43 (fourth bonding wire) electrically connects the electrode 23 of the semiconductor chip 25 to the electrode 32 (another end) of the capacitive component 34, and the bonding wire 44 (fifth bonding wire) electrically connects the electrode 32 of the capacitive component 34 to the output pattern 52. The internal output matching circuit 61 can be formed by the capacitive component 34, and the bonding wires 43 and 44.

### (First Variation of First Embodiment)

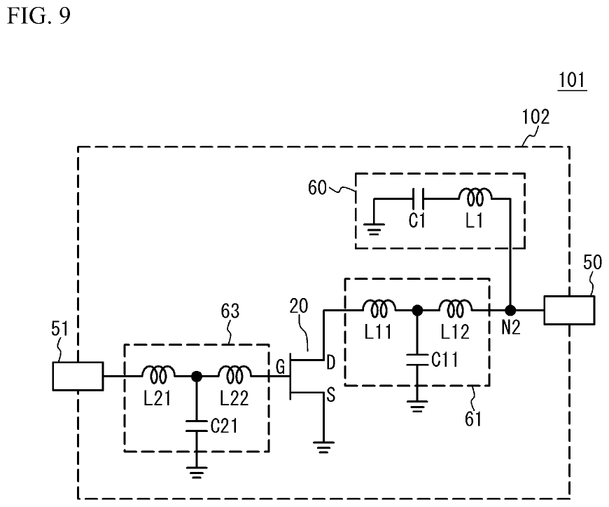

FIG. 9 is a circuit diagram illustrating a semiconductor device according to a first variation of the first embodiment. As illustrated in FIG. 9, in a semiconductor device 101 of the first variation of the first embodiment, the VBW circuit 60 is connected to a node N2 between the internal output matching circuit 61 and the output lead 50. Other circuit configurations are the same as those in FIG. 2 of the first embodiment, and the description thereof will be omitted.

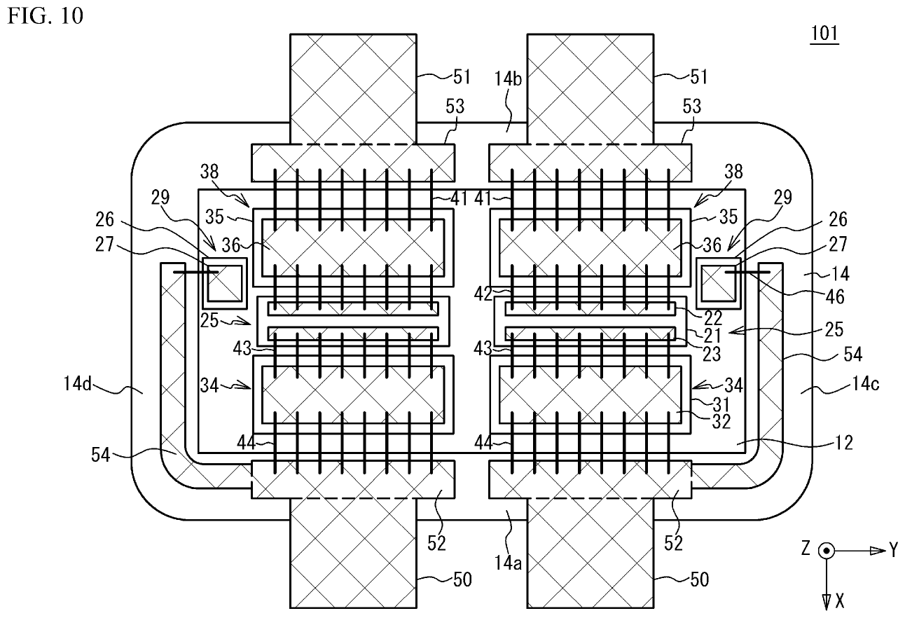

FIG. 10 is a plan view illustrating a semiconductor device according to a first variation of the first embodiment. As illustrated in FIG. 10, in the semiconductor device 101 of the first variation of the first embodiment, the wiring pattern 54 is connected to the output pattern 52 on the frame 14. The bonding wire 45 is not provided. Other circuit configurations are the same as those in FIG. 3 of the first embodiment, and the description thereof will be omitted.

The wiring pattern 54 may be electrically connected to the output pattern 52 on the frame 14 without providing the bonding wire 45 as in the first variation of the first embodiment. Thereby, the output pattern 52 functions as the node N2 in FIG. 9. The wiring pattern 54 and the bonding wire 46 function as the inductor L1. By forming the wiring pattern 54 on the upper surface of the frame 14, it is possible to reduce the size and the cost as in the first embodiment. Further, since the bonding wire 45 does not have to be provided, the coupling between the bonding wire 45 and another bonding wire does not occur. This can suppress the oscillation and instability of the amplifier.

At least a part of the wiring pattern 54 is located at a position in the Y direction with respect to the semiconductor chip 25. Thereby, the wiring pattern 54 can be lengthened, and the inductor L1 having a desired inductance can be formed.

The absolute value of the total impedance ZL of the bonding wire 46 and the wiring pattern 54 at the frequency f of the fundamental wave is greater than the absolute value of the impedance LC at the frequency Δf corresponding to the bandwidth of the capacitive component 29. By making the absolute value of the impedance ZL larger than the absolute value of the impedance LC, the inductor L1 and the capacitor C1 function as the VBW circuit 60. The absolute value of the impedance ZL is preferably 10 dB or more larger than the absolute value of the impedance ZC, and more preferably 20 dB or more.

### (Second Variation of First Embodiment)

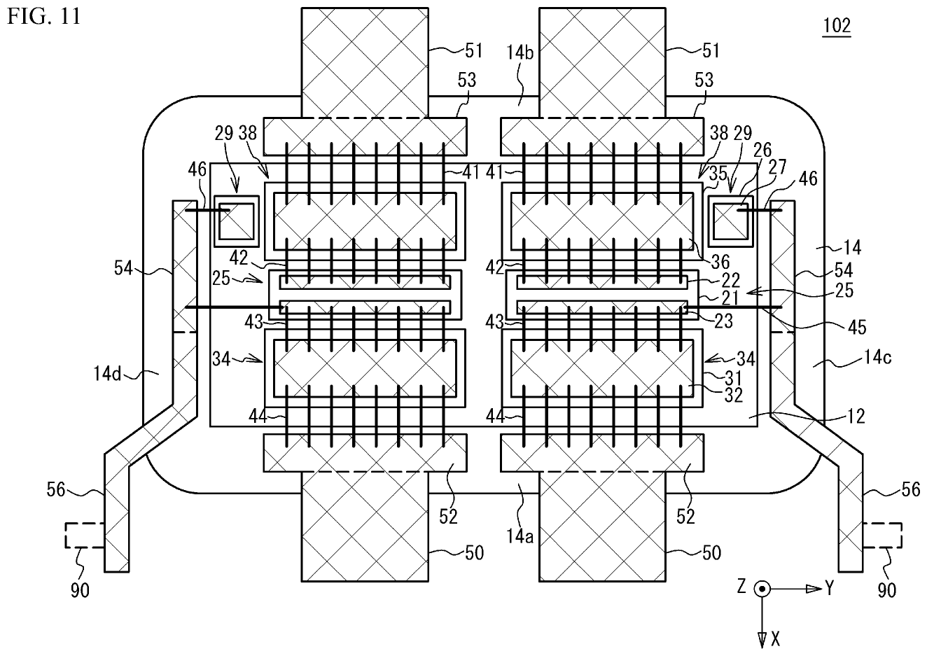

FIG. 11 is a plan view illustrating a semiconductor device according to a second variation of the first embodiment. As illustrated in FIG. 11, in a semiconductor device 102 of the second variation of the first embodiment, a lead 56 is provided on the frame 14. The lead 56 is electrically connected to the wiring pattern 54. The lead 56 is connected to an external capacitive component 90. The bonding wire 45, the wiring pattern 54, the bonding wire 46, and the lead 56 function as the inductor L1. The capacitive components 29 and 90 function as a capacitor C2. The lead 56 may be formed of the same metal layer as the wiring pattern 54. The lead 56 may be electrically bonded on the wiring pattern 54, for example, with the metal paste or the brazing material. Other circuit configurations are the same as those in the first embodiment, and the description thereof will be omitted. By providing the external capacitive component 90, the capacitance of the capacitor C1 of the VBW circuit 60 can be increased. This allows the impedance of capacitor C1 at a low frequency to be lowered, making it easier to design the VBW circuit 60.

### (Third Variation of First Embodiment)

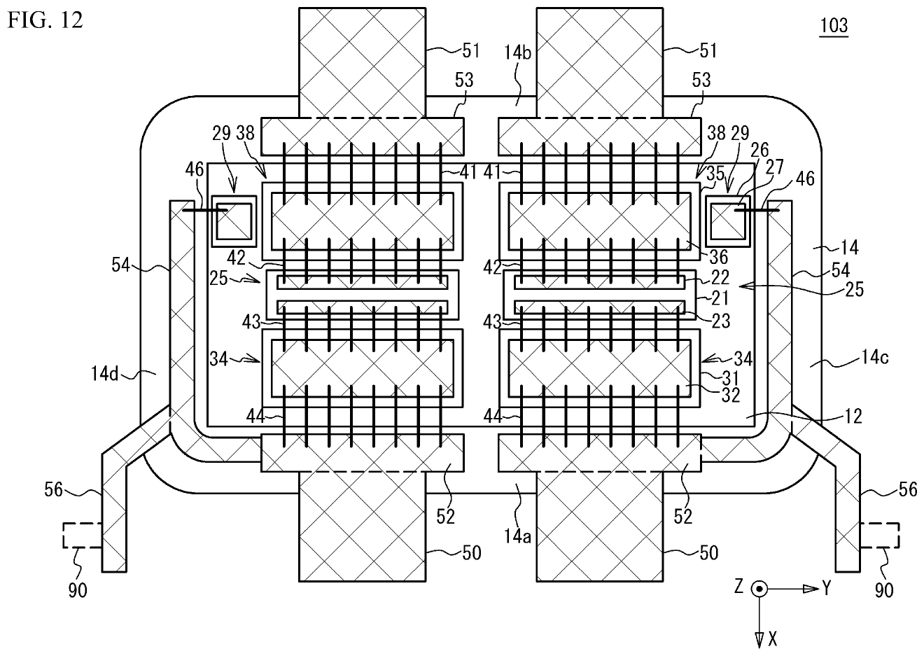

FIG. 12 is a plan view illustrating a semiconductor device according to a third variation of the first embodiment. As illustrated in FIG. 12, in a semiconductor device 103 of the third variation of the first embodiment, the lead 56 is electrically provided in the wiring pattern 54 of the first variation of the first embodiment. The wiring pattern 54, the bonding wire 46, and the lead 56 function as the inductor L1. The capacitive components 29 and 90 function as the capacitor C2. Other configurations are the same as those in the first and the second variations of the first embodiment, and the description thereof will be omitted. Since the bonding wire 45 does not have to be provided, the oscillation and the instability of the amplifier can be suppressed as in the first variation of the first embodiment. Further, by providing the external capacitive component 90, the capacitance of the capacitor C1 of the VBW circuit 60 can be increased as in the second variation of the first embodiment. This allows the impedance of capacitor C1 at the low frequency to be lowered, making it easier to design the VBW circuit 60.

As in the second and the third variation of the first embodiment, the lead 56 (external terminal) is a terminal electrically connected to the wiring pattern 54 and connected to the external capacitive component 90. Thereby, the capacitance of the capacitor C1 of the VBW circuit 60 can be increased. This allows the impedance of capacitor C1 at the low frequency to be lowered, making it easier to design the VBW circuit 60.

### (Fourth Variation of First Embodiment)

FIG. 13 is a plan view illustrating a semiconductor device according to a fourth variation of the first embodiment. As illustrated in FIG. 13, in a semiconductor device 104 of the fourth variation of the first embodiment, the capacitive component 34 is not provided, and the bonding wire 47 electrically connects the electrode 23 of the semiconductor chip 25 to the output pattern 52. That is, the bonding wire 47 is not connected to other capacitive components mounted on the base substrate 12, but connects the electrode 23 to the output pattern 52. Other configurations are the same as those in the first embodiment, and the description thereof will be omitted. The internal output matching circuit 61 does not have to be provided as in the fourth variation of the first embodiment. In the first to third variations of the first embodiment, the internal output matching circuit 61 does not have to be provided. By not providing the internal output matching circuit 61 on the base substrate 12, the semiconductor device can be reduced in size.

### (Fifth Variation of First Embodiment)

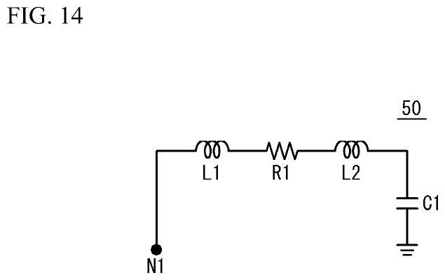

FIG. 14 is a circuit diagram illustrating a VBW circuit according to a fifth variation of the first embodiment. As illustrated in FIG. 14, a resistor R1 and an inductor L2 may be connected between the inductor L1 and the capacitor C1. When the capacitor C1 having a large capacitance is connected to the semiconductor chip 25 via the inductor L1, resonance occurs due to the capacitor C1, the inductor L1, and the parasitic capacitance internally included in the semiconductor chip 25. Therefore, the resonance can be suppressed by inserting a resistor R1 as illustrated in FIG. 14 to serve as a damping resistor. The inductor L2 corresponds to a bonding wire that connects the resistor R1 to the capacitor C1. Other configurations are the same as those in the first embodiment and the first to the fourth variations thereof, and the description thereof will be omitted.

### (Sixth Variation of First Embodiment)

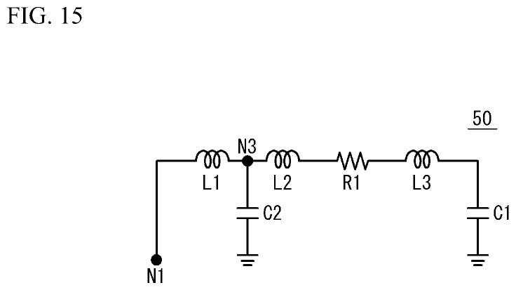

FIG. 15 is a circuit diagram illustrating a VBW circuit according to a sixth variation of the first embodiment. As illustrated in FIG. 15, the inductor L2, the resistor R1, and an inductor L3 are connected in series between the inductor L1 and the capacitor C1. A capacitor C2 is connected in parallel with the inductor L2, the resistor R1, the inductor L3 and the capacitor C1 between the ground and a node N3 between the inductors L1 and L2. The resistor R1 is the damping resistor, and the inductors L2 and L3 are the bonding wires to connect the resistor R1. The capacitance of the capacitor C2 is selected to be smaller than that of the capacitor C1. By adding the capacitor C2, the impedance in the low frequency band different from that of the capacitor C1 can be suppressed. This allows the VBW circuit 60 to be wideband. Other configurations are the same as those in the first embodiment and the first to the fourth variations thereof, and the description thereof will be omitted.

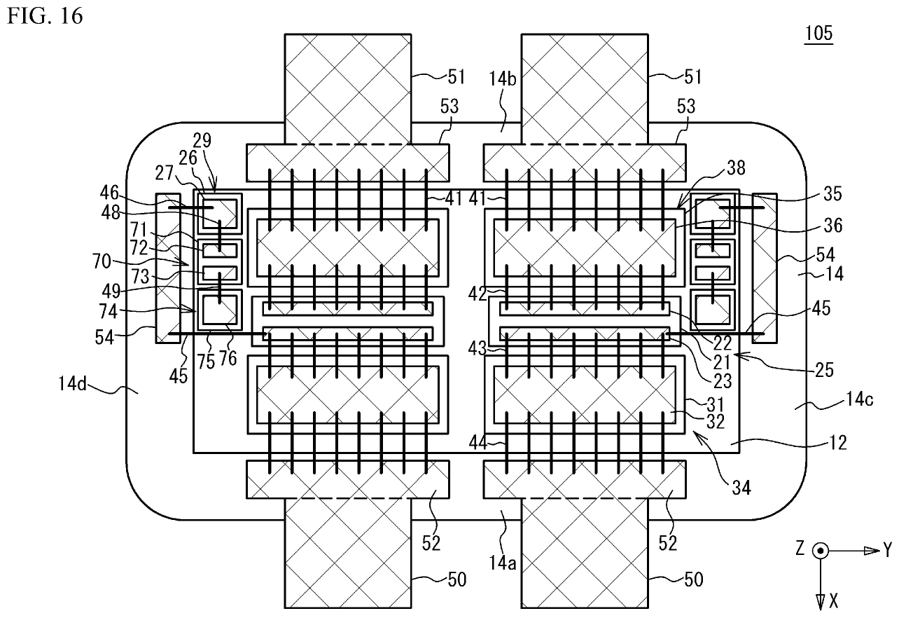

FIG. 16 is a plan view illustrating a semiconductor device according to the sixth variation of the first embodiment. As illustrated in FIG. 16, in a semiconductor device 105 of the sixth variation of the first embodiment, a resistive component 70 and a capacitive component 74 are mounted on the base substrate 12. The resistive component 70 includes a dielectric substrate 71 and electrodes 72 and 73 provided on the upper surface of the dielectric substrate 71. A resistor is connected between the electrodes 72 and 73. The capacitive component 74 includes a dielectric substrate 75 and an electrode 76 provided on the upper surface of the dielectric substrate 75. An electrode provided on the lower surface of the dielectric substrate 75 is electrically connected to the base substrate 12. A bonding wire 48 electrically connects the electrode 27 of the capacitive component 29 to the electrode 72 of the resistive component 70. A bonding wire 49 electrically connects the electrode 73 of the resistive component 70 to the electrode 76 of the capacitive component 74. The bonding wires 48 and 49 correspond to the inductors L2 and L3, respectively. The resistive component 70 and the capacitive component 74 correspond to the resistor R1 and the capacitor C1, respectively. By using the resistive component 70 and the capacitive component 74 in addition to the capacitive component 29, the sixth variation of the first embodiment of FIG. 15 can be realized. Other configurations are the same as those in the first embodiment, and the description thereof will be omitted.

The VBW circuit 60 may include an inductor, a capacitor and/or a resistor in addition to the inductor L and the capacitor C1, as in the fifth and the sixth variations 5 and 6 of the first embodiment. The bonding wire, the capacitive component, and resistive component may be used for the inductor, the capacitor, and the resistance, respectively, as in the sixth variation of the first embodiment.

### (Seventh Variation of First Embodiment)

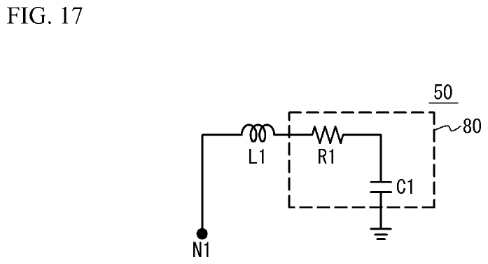

FIG. 17 is a circuit diagram illustrating a VBW circuit according to a seventh variation of the first embodiment. As illustrated in FIG. 17, the resistor R1 may be connected between the inductor L1 and the capacitor C1. The resistor R1 and the capacitor C1 may be provided in an IPD (Integrated Passive Device) 80. The resistor R1 functions as the damping resistance that suppresses the resonance. By forming the capacitor C1 and the resistor R1 in the IPD 80, it is possible to reduce the size of the component. Other configurations are the same as those in the first embodiment and the first to the fourth variations thereof, and the description thereof will be omitted.

### (Eighth Variation of First Embodiment)

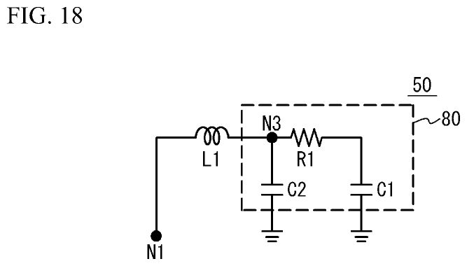

FIG. 18 is a circuit diagram illustrating a VBW circuit according to an eighth variation of the first embodiment. As illustrated in FIG. 18, the resistor R1 is connected in series between the inductor L1 and the capacitor C1. The capacitor C2 is connected in parallel with the resistor R1 and the capacitor C1 between the ground and the node N3 between the inductor L1 and the resistor R1. The resistor R1 functions as the damping resistor to suppress the resonance. By adding the capacitor C2 and using the capacitors C1 and C2 with different capacitances, the VBW circuit 60 can be widened. Other configurations are the same as those in the first embodiment and the first to the fourth variations thereof, and the description thereof will be omitted.

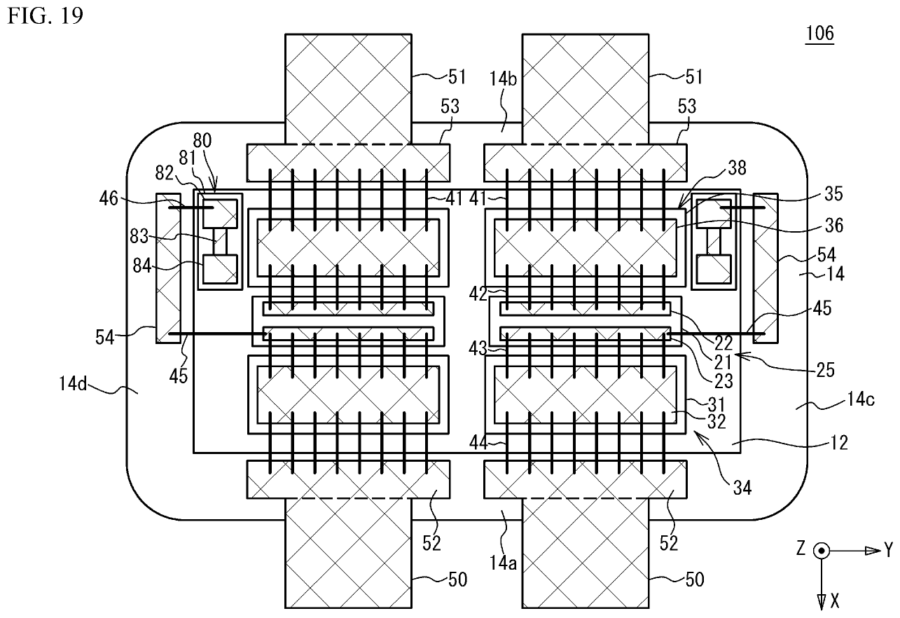

FIG. 19 is a plan view illustrating a semiconductor device according to the eighth variation of the first embodiment. As illustrated in FIG. 19, in a semiconductor device 106 of the eighth variation of the first embodiment, the IPD 80 is mounted on the base substrate 12. The IPD 80 includes a dielectric substrate 81, electrodes 82 and 84 provided on the upper surface of the dielectric substrate 81, and a resistor 83. An electrode electrically connected to the base substrate 12 is provided on the lower surface of the dielectric substrate 81. The electrodes 82 and 84 and the electrode on the lower surface that sandwich the dielectric substrate 81 form the capacitors C1 and C2, respectively. The IPD 80 is a capacitive component having the capacitor C1. The resistor 83 connected between the electrodes 82 and 84 forms the resistor R1. By forming the capacitors C1 and C2 and the resistor R1 in the IPD 80, it is possible to reduce the size of the component. Other configurations are the same as those in the first embodiment, and the description thereof will be omitted.

A part of the VBW circuit 60 may be formed by the IPD 80 as in the seventh and the eighth variations of the first embodiment. At least one of the inductor, the capacitor and the resistor may be formed by the IPD 80 as in the eighth variation of the first embodiment.

In the first embodiment and its variations, an example in which the inductor L1 and the capacitor C1 form the VBW circuit 60 is described. However, the inductor L1 and the capacitor C1 may be a circuit other than the VBW circuit 60, such as at least a part of the internal output matching circuit 61.

The embodiments disclosed here should be considered illustrative in all respects and not restrictive. The present disclosure is not limited to the specific embodiments described above, but various variations and changes are possible within the scope of the gist of the present disclosure as described in the claims.

What is claimed is:

1. A semiconductor device comprising:
a semiconductor chip mounted on an upper surface of a base substrate and having an output pad;
a first capacitive component mounted on the upper surface of the base substrate and having one end electrically connected to the base substrate;
a frame provided on the base substrate and made of a dielectric surrounding the semiconductor chip and the first capacitive component;
an output terminal provided on the frame;
a wiring pattern provided on an upper surface of the frame;
a first bonding wire electrically connecting the output pad to the output terminal;
a second bonding wire electrically connecting another end of the first capacitive component to a first region in the wiring pattern; and
a third bonding wire electrically connecting the output pad to a second region different from the first region in the wiring pattern.

2. The semiconductor device according to claim 1, further comprising:
an input terminal provided on the frame, facing the output terminal across the semiconductor chip, and electrically connected to an input pad of the semiconductor chip,
wherein an angle between a direction in which the third bonding wire extends and a direction in which the input terminal, the semiconductor chip and the output terminal are arranged is 30 degrees or more.

3. The semiconductor device according to claim 1, wherein
the semiconductor chip amplifies a high frequency signal and outputs the amplified high frequency signal to the output pad,
an absolute value of a total impedance of the second bonding wire, the third bonding wire and the wiring pattern at a frequency of the high frequency signal amplified by the semiconductor chip is greater than an absolute value of an impedance of the first capacitive component at a frequency corresponding to a bandwidth of the high frequency signal amplified by the semiconductor chip.

4. A semiconductor device comprising:
a semiconductor chip mounted on an upper surface of a base substrate and having an output pad;
a first capacitive component mounted on the upper surface of the base substrate and having one end electrically connected to the base substrate;
a frame provided on the base substrate and made of a dielectric surrounding the semiconductor chip and the first capacitive component;
an output terminal provided on the frame;
a wiring pattern provided on an upper surface of the frame and electrically connected to the output terminal on the frame;
a first bonding wire electrically connecting the output pad to the output terminal; and
a second bonding wire electrically connecting another end of the first capacitive component to a region in the wiring pattern.

5. The semiconductor device according to claim 4, wherein
the semiconductor chip amplifies a high frequency signal and outputs the amplified high frequency signal to the output pad,
an absolute value of a total impedance of the second bonding wire and the wiring pattern at a frequency of the high frequency signal amplified by the semiconductor chip is greater than an absolute value of an impedance of the first capacitive component at a frequency corresponding to a bandwidth of the high frequency signal amplified by the semiconductor chip.

6. The semiconductor device according to claim 1, further comprising:
an input terminal provided on the frame and electrically connected to an input pad of the semiconductor chip.

7. The semiconductor device according to claim 1, further comprising:
an external terminal electrically connected to the wiring pattern and connected to an external capacitive component.

8. The semiconductor device according to claim 1, wherein
the first bonding wire is not connected to another capacitive component mounted on the base substrate, but connects the output pad to the output terminal.

9. The semiconductor device according to claim 1, further comprising:
a second capacitive component mounted on the upper surface of the base substrate and having one end electrically connected to the base substrate,
wherein the first bonding wire includes a fourth bonding wire electrically connecting the output pad to another end of the second capacitive component, and a fifth bonding wire electrically connecting the another end of the second capacitive component to the output terminal.
